(19) United States
(12) Patent Application Publication
(10) Pub. No.: US 2011/0128505 A1
(43) Pub. Date: Jun. 2, 2011

(54) LASER BEAM SOURCE DEVICE, LASER BEAM SOURCE DEVICE MANUFACTURING METHOD, PROJECTOR, AND MONITORING DEVICE

(75) Inventor: Junichi OKAMOTO, Matsumoto-shi (JP)

(73) Assignee: SEIKO EPSON CORPORATION, Tokyo (JP)

(21) Appl. No.: 12/894,765

(22) Filed: Sep. 30, 2010

(30) Foreign Application Priority Data
Nov. 27, 2009 (JP) 2009-269675

(51) Int. Cl. G02B 27/10; G03B 21/00; G03F 7/20

(52) U.S. Cl. 353/31; 359/618; 430/321

(57) ABSTRACT

A laser beam source device includes: a first light emission element; a second light emission element; and first and second dividing units, wherein the first light emission portion of the first light emission element and the first light emission portion of the second light emission element, having a first clearance, are disposed such that the laser beam emitted from each of the light emission portions can enter the other light emission portion, the second light emission portion of the first light emission element and the second light emission portion of the second light emission element, having a second clearance, are disposed such that the laser beam emitted from each of the light emission portions enters the other light emission portion, and the first clearance is longer than the second clearance.

### BACKGROUND

1. Technical Field

The present invention relates to a laser beam source device, a laser beam source device manufacturing method, a projector, and a monitoring device.

2. Related Art

A high-pressure mercury lamp has been often used as an illumination light source of an optical apparatus such as a projector. However, the high-pressure mercury lamp has several problems such as limited color reproducibility, insufficient rapidity in lighting, and short life. For solving these problems, a laser beam source device applicable in this field has been under development. Particularly, a laser beam source device having an external resonator structure capable of intensifying light having a particular wavelength by using the external resonator has been developed to produce high output. In addition, a technology which generates light having a fundamental wavelength such as an infrared laser beam and then converts the infrared laser beam into visible light having a ½ wavelength by using a wavelength converging element such as a second harmonic generator (hereinafter abbreviated as SHG) has been employed.

According to this technology, the laser beam needs to be amplified by successive inductive discharge generated through reciprocation of the laser beam many times within a laser generator. However, when the optical axis of the laser beam deviates even only slightly, sufficient reciprocation of the laser beam cannot be achieved. In this case, lasers cannot be generated. According to the external resonator type laser beam source device, therefore, alignment (position matching) between a laser diode including an emitter (light emission portion) and an external resonating mirror is extremely important, and sufficient output cannot be produced when alignment accuracy is low. For preventing lowering of alignment accuracy caused by thermal lensing effect of a laser excitation medium, a method which uses a concaved reflection surface of an external resonating mirror has been proposed (for example, see JP-A-2004-363414). According to the description of this reference, the output laser beam reflected by the concaved reflection surface of the external resonating mirror returns toward the optical axis even when the output laser beam expands or deviates by the thermal lensing effect of the laser excitation medium. By this method, sufficient output is expected to be produced.

However, even when sufficient alignment accuracy is secured between the laser excitation medium and the external resonating mirror by using the method disclosed in JP-A-2004-363414, increase in the output of the laser is still limited. For further increasing the output, an external resonator structure which includes two laser diodes disposed optically opposed to each other has been studied. According to this external resonator structure, the laser diodes are provided at both ends of the resonator, and laser beams are amplified by successive inductive discharge generated through reciprocation of the laser beams between the two laser diodes. Moreover, the amplification of the laser beams is expected to be larger than that of a structure including the laser diode and the external resonating mirror, which allows the laser beam source device to be appropriate for high output.

According to this external resonator structure, however, emitters of the two laser diodes need to be accurately aligned for generating sufficient lasers. Thus, when the center axes of the laser beams emitted from the respective laser diodes deviate from each other even slightly, sufficient reciprocation of the laser beams cannot be achieved. In this case, lasers cannot be generated, or loss of the light amount is produced by inaccurate return of the laser beams toward the laser diodes. Therefore, the light source device provided with the external resonator structure which includes the two laser diodes disposed optically opposed to each other is difficult to be manufactured, and the output is lowered under the condition that the laser beams do not return to the laser diodes disposed opposed to each other with sufficient accuracy.

Moreover, according to the external resonator structure which has the two laser diodes optically opposed to each other, the size of the laser beam source device tends to increase.

### SUMMARY

An advantage of some aspects of the invention is to provide a laser beam source device, a laser beam source device manufacturing method, a projector, and a monitoring device, as a technology associated with a laser beam source provided with a resonator structure which contains light emission elements opposed to each other and capable of achieving high output and size reduction.

A laser beam source device according to an application example of the invention includes: a first light emission element having first and second light emission portions each of which emits a laser beam; a second light emission element having first and second light emission portions each of which emits a laser beam; and first and second dividing units disposed on optical paths of the laser beams emitted from the first light emission element and the second light emission element, respectively, to release a part of the received laser beams in directions different from directions toward the first light emission element and the second light emission element and release the remaining part of the laser beams in directions toward the first light emission element and the second light emission element. The first light emission portion of the first light emission element and the first light emission portion of the second light emission element are disposed in correspondence with each other such that the laser beam emitted from each of the light emission portions can enter the other light emission portion. The second light emission portion of the first light emission element and the second light emission portion of the second light emission element are disposed in correspondence with each other such that the laser beam emitted from each of the light emission portions enters the other light emission portion. The clearance between the first light emission portion of the first light emission element and the first light emission portion of the second light emission element is longer than the clearance between the second light emission portion of the first light emission element and the second light emission portion of the second light emission element.

According to the laser beam source device of the application example, the laser beam emitted from the light emission portion of the first light emission element enters the light emission portion of the second light emission element, and the laser beam emitted from the light emission portion of the second light emission element enters the light emission portion of the first light emission element. Then, a part of the laser beams having reciprocated between the light emission portion of the first light emission element and the light emission portion of the second light emission element are released in directions different from directions toward the first and second light emission elements by the function of the first and second dividing units. The remaining part of the laser beams are released in directions toward the first and second light emission elements by the function of the first and second dividing units. By this method, the efficiency of using light improves, and the output increases.

The clearance between the first light emission portion of the first light emission element and the first light emission portion of the second light emission element is longer than the clearance between the second light emission portion of the first light emission element and the second light emission portion of the second light emission element. By this arrangement, the degree of freedom in positioning the first light emission portions and the second light emission portions in the plan view increases, and thus the laser beam source device becomes compact.

It is preferable that the laser beam source device of the application example of the invention satisfies the following point: the first dividing unit and the second dividing unit are disposed on the optical paths such that the optical path length between the first light emission portion of the first light emission element and the first dividing unit is shorter than the optical path length between the second light emission portion of the first light emission element and the first dividing unit, that the optical path length between the first light emission portion of the second light emission element and the second dividing unit is shorter than the optical path length between the second light emission portion of the second light emission element and the second dividing unit, and that the optical path lengths of the laser beams emitted from the first light emission portions between the first dividing unit and the second dividing unit are longer than the optical path lengths of the laser beams emitted from the second light emission portions between the first dividing unit and the second dividing unit.

According to this laser beam source device, the difference between the optical path length between the respective first light emission portions and the optical path length between the respective second light emission portions can be reduced or eliminated. In this structure, alignment can be easily carried out, and the output can be raised by the equalized optical path condition. Moreover, the arrangement of the respective components can be made compact, and the size of the laser beam source device can be decreased.

It is preferable that the laser beam source device of the application example of the invention satisfies the following points: each of the first light emission portion of the first light emission element and the first light emission portion of the second light emission element has a plurality of light emission sections; the arrangement direction of the plural light emission sections of the first light emission portion of the first light emission element extends substantially in parallel with the arrangement direction of the plural light emission sections of the first light emission portion of the second light emission element; the clearance between each pair of the adjoining light emission sections of the first light emission portion of the first light emission element is substantially equal to the clearance between each pair of the adjoining light emission sections of the first light emission portion of the second light emission element; laser beams emitted from the plural light emission sections of the first light emission element enter the first dividing unit; and laser beams emitted from the plural light emission sections of the second light emission element enter the second dividing unit.

According to this laser beam source device, the arrangement direction of the plural light emission sections of the first light emission portion of the first light emission element is substantially parallel with the arrangement direction of the plural light emission sections of the first light emission portion of the second light emission element, and the clearance between each pair of the adjoining light emission sections of the first light emission portion of the first light emission element is substantially equal to the clearance between each pair of the adjoining light emission sections of the first light emission portion of the second light emission element. In this arrangement, the plural light emission sections of the first light emission portion of the first light emission element and the plural light emission sections of the first light emission portion of the second light emission element are accurately aligned. Thus, the laser beams emitted from the plural light emission sections of the one light emission element can accurately enter toward the other laser beams.

Moreover, the laser beams emitted from the plural light emission sections of the first light emission portion of the first light emission element enter the first dividing unit, and the laser beams emitted from the plural light emission sections of the first light emission portion of the second light emission element enter the second dividing unit. In this case, the plural laser beams can be collectively divided, and thus the first and second dividing units can be easily positioned.

It is preferable that the laser beam source device of the application example of the invention satisfies the following point: the color of the light emitted from the first light emission portion is different from the color of the light emitted from the second light emission portion.

According to this laser beam source device as a laser beam source device capable of emitting different color lights by a compact structure, the size of the device can be reduced.

It is preferable that the laser beam source device of the application example of the invention satisfies the following points: each of the first light emission element and the second light emission element has the first light emission portion, the second light emission portion, and a third light emission portion; the color of the light emitted from the third light emission portion is different from the colors of the lights emitted from the first light emission portion and the second light emission portion; the clearance between the respective first light emission portions of the first light emission element and the second light emission element is longer than the clearance between the respective second light emission portions of the first light emission element and the second light emission element; and the clearance between the respective second light emission portions of the first light emission element and the second light emission element is longer than the clearance between the respective third light emission portions of the first light emission element and the second light emission element.

According to this laser beam source device as a laser beam source device capable of emitting different color lights by a compact structure, the size of the device can be reduced.

Moreover, the optical path lengths of the respective light emission portions emitting different color lights can be equalized. Thus, the beam waists of the laser beams in the respective colors can be aligned, and the focus position produced by thermal lensing effect can be considered to lie at the same position.

It is preferable that the laser beam source device of the application example of the invention further includes: a wavelength converting element disposed on the optical path between the first dividing unit and the second dividing unit to receive respective laser beams having a fundamental wavelength and emitted from the first light emission element and the second light emission element and convert at least a part of the laser beams having the fundamental wavelength into laser beams having a predetermined converted wavelength. In this case, the first and second dividing units release the converted laser beams having the predetermined converted wavelength in directions different from directions toward the first and second light emission elements and release the laser beams having the fundamental wavelength and not converted into beams of the predetermined converted wavelength in directions toward the first and second light emission elements.

According to this laser beam source device, at least a part of the laser beams having the fundamental wavelength and emitted from the first and second light emission elements are converted into laser beams having the predetermined converted wavelength while passing through the wavelength converting element. Then, the converted laser beams having the predetermined converted wavelength are released in directions different from directions toward the first and second light emission elements, and the laser beams having the fundamental wavelength and not converted into beams of the predetermined converted wavelength are released toward the first and second light emission elements. Thus, infrared laser beams can be converted into laser beams as visible lights, for example, by using the wavelength converting element. Accordingly, laser beams having a desired wavelength can be produced.

It is preferable that the laser beam source device of the application example of the invention satisfies the following point: the light emission portion of the first light emission element and the light emission portion of the second light emission element are provided on a laser substrate.

According to this laser beam source device, the light emission portion of the first light emission element and the light emission portion of the second light emission element are disposed on the one laser substrate. Thus, laser beams can be accurately supplied to the opposed light emission element. In this case, the laser beams emitted from the respective light emission portions of the first and second light emission elements can enter the opposed light emission element without loss of laser beams. Accordingly, the efficiency of using light improves, and the output increases.

Moreover, the plural light emission portions are provided on the same laser substrate. Thus, the number of the light emission portions formed on the one laser substrate increases.

A laser beam source device manufacturing method for manufacturing the laser beam source device described above according to another application example of the invention includes forming the first light emission element and the second light emission element on the laser substrate by using photolithography.

According to the laser beam source device manufacturing method of the application example, the first and second light emission elements are formed by using photolithography. Thus, the first light emission element and the second light emission element can be positioned with accuracy of several tens nm. Thus, the first light emission element and the second light emission element can be accurately formed by the easy method.

A projector according to still another application example of the invention includes: the laser beam source device described above; a light modulation device which modulates a laser beam emitted from the laser beam source device according to an image signal; and a projection device which projects light modulated by the light modulation device.

According to this laser projector, light emitted from the laser beam source device enters the light modulation device. Then, an image formed by the light modulation device is projected by the projection device. In this case, the light emitted from the light source device is constituted by high-output laser beams as described above. Thus, the image to be displayed becomes a bright and clear image.

A monitoring device according to yet another application example of the invention includes: the laser beam source device described above; and an image pickup unit which captures an image of a subject by using light emitted from the laser beam source device.

According to this monitoring device, laser beams emitted from the laser beam source device are applied to the subject, and an image of the subject is captured by the image pickup unit. In this case, the applied laser beams are constituted by high-output laser beams as described above, which allows the subject to be illuminated by bright light. Accordingly, a clear image of the subject can be captured by the image pickup unit.

### BRIEF DESCRIPTION OF THE DRAWINGS

The invention will be described with reference to the accompanying drawings, wherein like numbers reference like elements.

FIG. 1 is a plan view illustrating a laser beam source device according to a first embodiment of the invention.

FIG. 2 is a top view illustrating first and second light emission elements shown in FIG. 1.

FIG. 3 is a plan view illustrating a laser beam source device according to a second embodiment of the invention.

FIG. 4 is a top view illustrating first and second light emission elements shown in FIG. 3.

FIG. 5 is a plan view illustrating a laser beam source device according to a third embodiment of the invention.

FIG. 6 is a top view illustrating first and second light emission elements shown in FIG. 5.

FIG. 7 is a top view illustrating a manufacturing method of the laser beam source device shown in FIG. 5.

FIG. 8 is a top view illustrating the manufacturing method of the laser beam source device shown in FIG. 5.

FIG. 9 illustrates the general structure of a projector according to a fourth embodiment of the invention.

FIG. 10 illustrates the general structure of a scanning-type image display apparatus according to a fifth embodiment of the invention.

FIG. 11 illustrates the general structure of a monitoring device according to a sixth embodiment of the invention.

### DESCRIPTION OF EXEMPLARY EMBODIMENTS

A laser beam source device, a laser beam source device manufacturing method, a projector, and a monitoring device embodying the invention are hereinafter described with reference to the drawings. In the figures referred to herein, the reduction scales of the respective components are varied as necessary for easily recognizing the components in the figures.

### First Embodiment

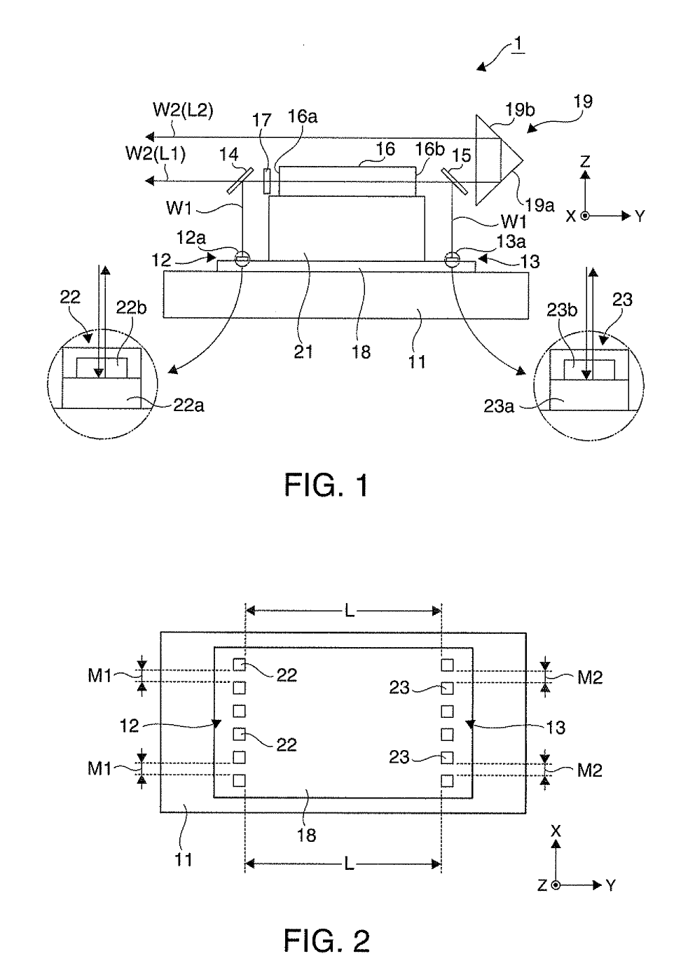

As illustrated in FIG. 1, a laser beam source device 1 includes a base 11, a first semiconductor laser element (first light emission element) 12, a second semiconductor laser element (second light emission element) 13, a first dichroic mirror (first dividing unit) 14, a second dichroic mirror (second dividing unit) 15, a wavelength converting element 16, and an optical path changing prism 19.

The emission directions of laser beams emitted from the first and second semiconductor laser elements 12 and 13 correspond to a Z axis direction, the arrangement directions of emitters 22 and 23 described later correspond to an X axis direction, and the axis crossing the emission directions and the arrangement directions at right angles corresponds to a Y axis direction.

The first and second semiconductor laser elements 12 and 13 are disposed on a laser substrate 18 provided on the base 11 such that their emission end surfaces 12a and 13a face upward in the figure. That is, both the laser beams emitted from the first and second semiconductor laser elements 12 and 13 travel in the Z axis direction.

The first dichroic mirror 14, the wavelength converting element 16, and the second dichroic mirror 15 are disposed on the optical paths of the laser beams emitted from the first and second semiconductor laser elements 12 and 13 in this order in the direction from the first semiconductor laser element 12 to the second semiconductor laser element 13.

As illustrated in FIG. 1, the first and second semiconductor laser elements 12 and 13 are provided on the one laser substrate 18 disposed on the base 11.

Each of the first and second semiconductor laser elements 12 and 13 is a face-emission-type laser diode which emits infrared laser beams having a wavelength of 1,060 nm (lights having a fundamental wavelength) from the emission end surfaces 12a and 13a, for example. As illustrated in FIG. 2, a plurality of rectangular emitters (light emission portions) 22 and 23 in the plan view are formed on the first and second semiconductor laser elements 12 and 13, respectively. More specifically, the first and second semiconductor laser elements 12 and 13 have the plural emitters 22 and 23 in the X axis direction. The plural (six in the example of the figure) emitters 22 of the first semiconductor laser element 12 and the plural (six in the example of the figure) emitters 23 of the second semiconductor laser element 13 are provided with one-to-one correspondence.

The first and second semiconductor laser elements 12 and 13 are formed on the laser substrate 18 by a semiconductor process using photolithography. By this method, the arrangement direction of the plural emitters 22 becomes parallel with the arrangement direction of the plural emitters 23, that is, all clearances L between the plural pairs of the emitter 22 and the corresponding emitter 23 disposed adjacent to the emitter 22 in the Y axis direction become uniform as illustrated in FIG. 2. In addition, each clearance MI between the adjoining emitters 22 in the X axis direction becomes substantially equal to each clearance M2 between the adjoining emitters 23 in the X axis direction.

As illustrated in the enlarged view in FIG. 1, each of the emitters 22 has an active layer 22b laminated on a DBR (distributed Bragg reflector) layer 22a. Similarly to the emitters 22, each of the emitters 23 has an active layer 23b laminated on a DBR layer 23a.

In this arrangement, a laser beam emitted from the first semiconductor laser element 12 enters the second semiconductor laser element 13, and a laser beam emitted from the second semiconductor laser element 13 enters the first semiconductor laser element 12. By this method, lasers are generated through reciprocation of the laser beams between the first semiconductor laser element 12 and the second semiconductor laser element 13. Thus, the first and second semiconductor laser elements 12 and 13 constitute a laser beam source.

As can be seen from FIG. 1, the wavelength converting element 16 is disposed between the first dichroic mirror 14 and the second dichroic mirror 15. The wavelength converting element 16 is located on a supporting member 21 mounted on the laser substrate 18 at such a position as to receive all laser beams emitted from the plural emitters 22 through an end surface 16a and receive all laser beams emitted from the plural emitters 23 through an opposite end surface 16b.

The wavelength converting element 16 is constituted by PPLN (periodically poled lithium niobate) as a non-linear optical element, and functions as SHG which converts entering light into light having a substantially half wavelength and generates second higher harmonic waves.

As illustrated in FIG. 1, a part of light emitted from the first semiconductor laser element 12 and supplied toward the second semiconductor laser element 13 is converted into green laser beams having a substantially half wavelength (530 nm) (light having a predetermined converted wavelength) while passing through the wavelength converting element 16. Similarly, a part of light emitted from the second semiconductor laser element 13 and supplied toward the first semiconductor laser element 12 is converted into green laser beams.

As illustrated in FIG. 2, the first and second dichroic mirrors 14 and 15 are mirrors which receive the laser beams emitted from the plural emitters 22 and 23, reflect infrared laser beams toward the first and second semiconductor laser elements 12 and 13, and transmit visible lights in directions different from directions toward the first and second semiconductor laser elements 12 and 13.

The first dichroic mirror 14 is disposed in such a direction as to receive the laser beam emitted from the first semiconductor laser element 12 at approximately 45 degrees and reflect the laser beam toward the wavelength converting element 16.

The second dichroic mirror 15 is disposed in such a direction as to receive the laser beam emitted from the second semiconductor laser element 13 at approximately 45 degrees and reflect the laser beam toward the wavelength converting element 16.

In this arrangement, the infrared laser beam emitted from the first semiconductor laser element 12, reflected by the first dichroic mirror 14, and not converted into a green laser beam while passing through the wavelength converting element 16 is reflected by the second dichroic mirror 15 and enters the second semiconductor laser element 13. More specifically, an infrared laser beam W1 emitted from the first semiconductor laser beam element 12 resonates between the DER layer 22a of the first semiconductor laser element 12 and the DBR layer 23a of the second semiconductor laser element 13 to be amplified. The infrared laser beam W1 emitted from the second semiconductor laser element 13 is amplified in the similar manner.

On the other hand, at least a part of the laser beams emitted from the first and second semiconductor laser elements 12 and 13 are converted into green lights while passing through the wavelength converting element 16. A laser beam W2 converted into green light passes through the first dichroic mirror 14 and is released in the -Y axis direction, or passes through the second dichroic mirror 15 and is released in the +Y axis direction.

As illustrated in FIG. 1, the optical path changing prism 19 is disposed on the optical path of the laser beam having passed through the second dichroic mirror 15, and fixed to the base 11 by a not-shown holding member. The optical path changing prism 19 converts the direction of the optical path of the green laser beam transmitted by the second dichroic mirror 15 into substantially the same direction as the direction of the green laser beam transmitted by the first dichroic mirror 14.

More specifically, the optical path changing prism 19 is a right-angled triangular prism which reflects the laser beam transmitted by the second dichroic mirror 15 by a first surface 19a and further by a second surface 19b inclined to the first surface 19a at 90 degrees. The optical path changing prism 19 having this structure changes the optical path of the laser beam transmitted by the second dichroic mirror 15 by 90 degrees. Thus, a laser beam L1 transmitted by the second dichroic mirror 15 and a laser beam L2 transmitted by the first dichroic mirror 14 become substantially parallel with each other.

A BPF (band-pass filter) 17 is disposed between the first dichroic mirror 14 and the wavelength converting element 16. The BPF 17 transmits only light having a predetermined converting wavelength to limit the spectrum of the emission wavelength. Thus, the green laser beam can be outputted in a stable manner by the function of the BPF 17.

According to the laser beam source device 1 in this embodiment, the first semiconductor laser element 12 and the second semiconductor laser element 13 are provided on the one laser substrate 18. In this structure, the laser beams can be supplied to the light emission elements opposed to each other with high alignment accuracy. In this case, the laser beams emitted from the emitters 22 and 23 of the first and second semiconductor laser elements 12 and 13 can be supplied to the opposed light emission elements without loss. Thus, the efficiency of using light improves, and the output increases.

Moreover, the plural emitters 22 and 23 included in the first and second semiconductor laser elements 12 and 13 are provided on the one laser substrate 18. Thus, the plural emitters 22 and 23 can be disposed with high alignment accuracy.

Furthermore, the first and second semiconductor laser elements 12 and 13 are formed on the laser substrate 18 by the semiconductor process using photolithography. Thus, the first and second semiconductor laser elements 12 and 13 can be aligned with accuracy of several tens nm. Thus, the first and second semiconductor laser elements 12 and 13 can be provided on the laser substrate 18 by a simplified method with high accuracy.

Therefore, the laser beam source device 1 and the manufacturing method of the laser beam source device 1 according to this embodiment can achieve high output.

The wavelength converting element 16 is not an essential component. When the wavelength converting element 16 is not equipped, the clearance L between the first semiconductor laser element 12 and the second semiconductor laser element 13 can be reduced. Thus, the number of the first and second semiconductor laser elements 12 and 13 disposed on the one laser substrate 18 can be increased. In this case, the first and second dividing units are not limited to the first and second dichroic mirrors 14 and 15 but may be other units as long as the first dividing unit can release the laser beam converted into a predetermined condition in a direction different from the direction toward the first semiconductor laser element 12 and release the laser beam not converted into the predetermined condition in the direction toward the first semiconductor laser element 12. This applies to the second dividing unit.

While the case in which the laser substrate 18 includes the first and second semiconductor laser elements 12 and 13 having the plural emitters 22 and 23 has been discussed, the laser substrate may include the first semiconductor laser element 12 and the second semiconductor laser element 13 each of which has only the one emitter 22 or the one emitter 23.

The method of forming the first and second semiconductor laser elements 12 and 13 on the laser substrate 18 is not limited to photolithography but may be any method as long as the laser beam emitted from the emitter of the one laser element can enter the emitter of the other laser element.

### Second Embodiment

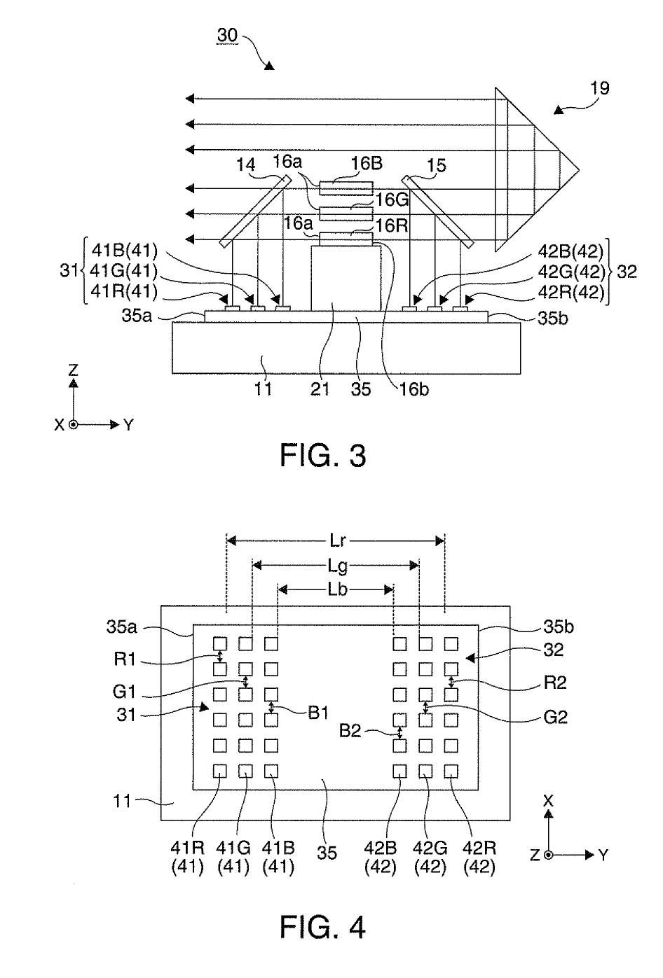

A second embodiment according to the invention is now described with reference to FIG. 3. In the figures associated with the respective embodiments, the same reference numbers are given to parts similar to those of the laser beam source device 1 in the first embodiment, and the same explanation is not repeated.

This embodiment is different from the first embodiment in that a laser beam source device 30 includes first and second semiconductor laser elements 31 and 32 having emitters 41 and 42 for emitting plural color lights, respectively. Other structures are similar to those of the first embodiment.

As illustrated in FIG. 3, the first semiconductor laser element 31 has red light emitters (first light emission portions or red light emission portions) 41R for emitting infrared laser beams having a wavelength of 1,240 nm (light having a fundamental wavelength), green light emitters (second light emission portions or green light emission portions) 41G for emitting infrared laser beams having a wavelength of 1,060 nm (light having a fundamental wavelength), and blue light emitters (third light emission portions or blue light emission portions) 418 for emitting infrared laser beams having a wavelength of 920 nm (light having a fundamental wavelength). Each number of the emitters 41R, 41G, and 41B is six.

Similarly, the second semiconductor laser element 32 has red light emitters (first light emission portions or red light emission portions) 42R, green light emitters (second light emission portions or green light emission portions) 42G, and blue light emitters (third light emission portions or blue light emission portions) 428 as illustrated in FIG. 3.

As can be seen from FIG. 4, the first semiconductor laser element 31 and the second semiconductor laser element 32 are provided on a laser substrate 35 disposed on the base 11 similarly to the first embodiment. The red light emitters 41R and 42R for emitting the same color lights are disposed at an end 35a of the laser substrate 35 and an opposite end 35b thereof, respectively. The green light emitters 41G and 42G are disposed at positions shifted from the red light emitters 41R and 42R toward the center, and the blue light emitters 41B and 42B are disposed at positions further shifted from the green light emitters 41G and 42G toward the center. In this arrangement, a clearance Lr between each pair of the red light emitters 41R and 42R is longer than a clearance Lg between each pair of the green light emitters 41G and 42G, and the clearance Lg between each pair of the green light emitters 41G and 42G is longer than a clearance Lb between each pair of the blue light emitters 41B and 42B.

A clearance R1 between each pair of the adjoining red light emitters 41R in the X axis direction on the first semiconductor laser element 31 is substantially equal to a clearance R2 between each pair of the adjoining red light emitters 42R in the X axis direction on the second semiconductor laser element 32. Similarly, a clearance G1 between each pair of the green light emitters 41G is substantially equal to a clearance G2 between each pair of the green light emitters 42G, and a clearance B1 between each pair of the blue light emitters 413 is substantially equal to a clearance B2 between each pair of the blue light emitters 423.

The plural emitters 41R, 41G, and 41B and the plural emitters 42R, 42G, and 423 are disposed such that the arrangement directions of the emitters for emitting the same color lights extend in parallel with each other. That is, the clearances Lr between the respective pairs of the red light emitter 41R and the corresponding red light emitter 42R as pairs disposed adjacent to each other in the X axis direction are equalized. This applies to the green light emitters and the blue light emitters.

A red light wavelength converting element 16R, a green light wavelength converting element 16G, and a blue light wavelength converting element 163 are provided in this order for each color light in the direction from the supporting member 21 side. That is, the red light wavelength converting element 16R is provided on the supporting member 21, the green light wavelength converting element 16G is provided above the red light wavelength converting element 16R as viewed in the figure (Z axis direction), and the blue light wavelength converting element 168 is provided above the green light wavelength converting element 16G as viewed in the figure (Z axis direction).

The first and second dichroic mirrors 14 and 15 are disposed in such positions that the laser beams emitted from the red light emitters 41R can pass through the red light wavelength converting element 16R and enter the red light emitters 42R, that the laser beams emitted from the green light emitters 41G can pass through the green light wavelength converting element 16G and enter the green light emitters 42G, and that the laser beams emitted from the blue light emitters 41B can pass through the blue light wavelength converting element 16B and enter the blue light emitters 42B. In this case, the optical path lengths between the laser beams emitted from the red light emitters 41R and 42R disposed closest to the ends 35a and 35b of the laser substrate 35 and the first and second dichroic mirrors 14 and 15 are shortest, and the optical path lengths, sequentially increase in the order of the laser beams emitted from the green light emitters 41G and 42G and the laser beams emitted from the blue light emitters 41B and 42B. Concerning the respective optical distances between the first and second dichroic mirrors 14 and 15 and one end surfaces 16a of the wavelength converting elements 16 and the other end surfaces 16b of the wavelength converting elements 16, the optical path lengths of the laser beams emitted from the red emitters 41R and 42R are the longest, and the optical path lengths sequentially decrease in the order of the laser beams emitted from the green light emitters 41G and 42G and the laser beams emitted from the blue light emitters 41B and 42B. Concerning the respective optical distances between the first dichroic mirror 14 and the second dichroic mirror 15, the optical path lengths of the laser beams emitted from the red emitters 41R and 42R are the longest, and the optical path lengths sequentially decrease in the order of the laser beams emitted from the green light emitters 41G and 42G and the laser beams emitted from the blue light emitters 41B and 42B.

Thus, all the optical path lengths of the laser beams emitted from the respective emitters 41R, 41G, 41B, 42R, 42G, and 42B and supplied to the wavelength converting elements 16 become substantially uniform.

Accordingly, the laser beam source device 30 in this embodiment can offer advantages similar to those of the laser beam source device 1 in the first embodiment. Moreover, the laser beam source device 30 has a compact structure and produces high output. Furthermore, since the dichroic mirrors and the optical path changing prism are provided as common components for the different emitters, the laser beam source device can be manufactured at low cost.

According to the laser beam source device 30 in this embodiment, the emitters 41R, 41G, 41B, 42R, 42G, and 42B for the three colors are formed on the same laser substrate 35. Thus, the number of the emitters provided on the one laser substrate 35 can be increased.

In addition, in the structure in which the clearances between the corresponding emitters are varied, the clearance Lb where no emitters are provided becomes shorter than the clearance L in the first embodiment. Thus, a waste area can be reduced. Moreover, the optical path lengths of the laser beams emitted from the respective emitters 41R, 41G, 41B, 42R, 42G, and 42B become substantially uniform.

In this structure, the beam waists of the laser beams in the respective colors can be aligned. Since the wavelength conversion efficiency increases when the wavelength converting elements are disposed at the positions of the beam waists, the positions of the wavelength converting elements for the respective colors can be aligned. Also, the focus position produced by the thermal lensing effect can be considered to lie at the same position.

According to this embodiment, the numbers of the respective emitters 41R, 41G, 41B, 42R, 42G, and 42B may be one for each.

In this case, the clearances between the pairs of the corresponding emitters can be varied similarly to the case described above. Thus, the emitters for the respective colors can be disposed in a compact arrangement. In addition, the optical component of the combining system used for combining the outputted lights can be small-sized. Accordingly, the high-output laser beam source device can be made compact.

According to this structure, the first semiconductor laser element 31 and the second semiconductor laser element 32 are not required to be equipped on the one laser substrate 35. The respective emitters may be provided on different laser substrates.

In this case, the clearances between the pairs of the corresponding emitters can be varied similarly to the case described above. Thus, the plural emitters can be disposed in a compact arrangement. Accordingly, the high-output laser beam source device can be made compact.

While the laser beam source device 30 in this embodiment emits red light, green light, and blue light, the laser beam source device may emit one color light. In this structure, the wavelengths of all the infrared laser beams emitted from the plural emitters are equalized.

In this case, the clearances between the pairs of the corresponding emitters can be varied similarly to the case described above. Thus, the emitters for emitting the one color can be disposed in a compact arrangement. In addition, the optical component of the combining system used for combining the outputted lights can be small-sized. Accordingly, the high-output laser beam source device can be made compact.

While the red light emitters 41R and 42R, the green light emitters 41G and 42G, and the blue light emitters 41B and 42B are disposed in this order from the ends 35a and 35b of the laser substrate 35 to the center in this embodiment, the order of the respective emitters is not limited to this order.

Even when the emitters for the respective colors are disposed in a different order, the laser beam source device capable of emitting different color lights can be made compact similarly to the case described above. Thus, the size of the device can be reduced.

### Third Embodiment

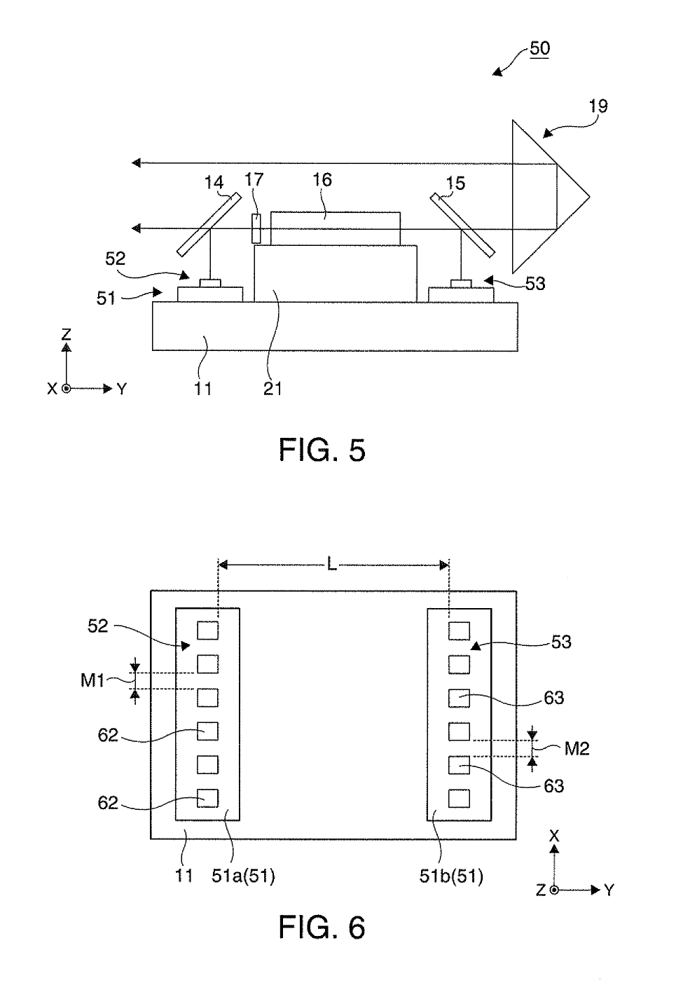

A third embodiment according to the invention is now described with reference to FIGS. 5 through 8.

This embodiment shows a method for manufacturing a laser beam source device 50 illustrated in FIG. 5 which includes a laser substrate 51 having a shape different from that of the corresponding component in the first embodiment.

As illustrated in FIG. 6, the laser substrate 51 has a first laser substrate 51a where a plurality of first emitters (first light emission portions) 62 of a first semiconductor laser element 52 are formed, and a second laser substrate 51b where a plurality of second emitters (second light emission portions) 63 of a second semiconductor laser element 53 are formed. In the example shown in FIG. 6, the six first emitters 62 and the six second emitters 63 are provided.

As can be seen from FIG. 6, all the clearances L between the respective pairs of the first emitter 62 and the corresponding second emitter 63 formed on the first and second laser substrates 51a and 51b are uniform similarly to the first embodiment. Also, the clearance M1 between each pair of the adjoining first emitters 62 in the X axis direction is substantially equivalent to the clearance M2 between each pair of the adjoining second emitters 63 in the X axis direction.

The specific examples of the material of the base 11 are silicon (Si), quartz (SiO₂), and sapphire (Al₂O₃).

The method of manufacturing the laser beam source device 50 having this structure according to this embodiment is now explained.

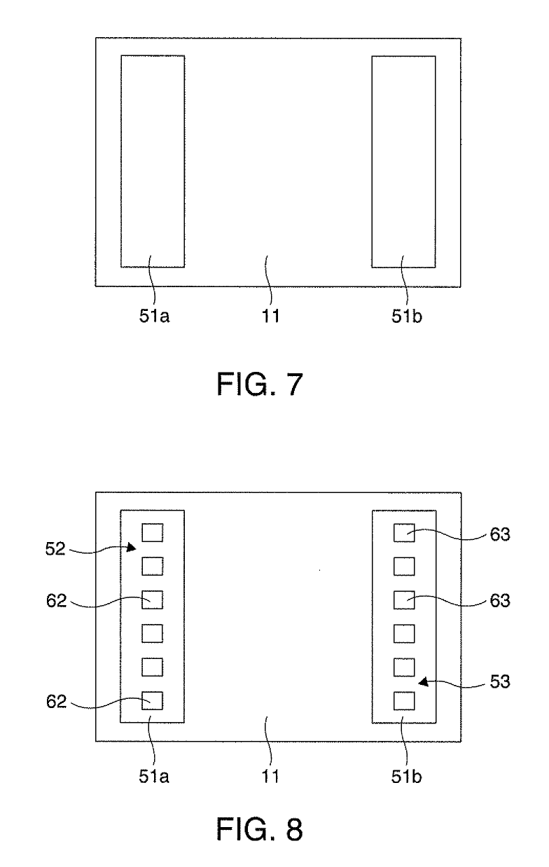

As illustrated in FIG. 7, the first laser substrate 51a and the second laser substrate 51b are disposed on the base 11 and bonded thereto. For bonding, plasma, dry film, spin-on adhesive, wax or the like may be used. It is preferable that the first laser substrate 51a and the second laser substrate 51b are disposed in parallel with each other, but are not required to be positioned in parallel.

Next, as illustrated in FIG. 8, the plural first emitters 62 are formed on the first laser substrate 51a by the semiconductor process using photolithography, and the plural second emitters 63 are formed on the second laser substrate 51b in correspondence with the plural first emitters 62 by the semiconductor process using photolithography.

Then, the first and second dichroic mirrors 14 and 15 and the wavelength converting element 16 are disposed at predetermined positions to manufacture the laser beam source device 50 shown in FIG. 5.

According to the laser beam source device 50 in this embodiment, the first and second emitters 62 and 63 are formed after the first and second laser substrates 51a and 51b are bonded to the base 11. Thus, even when the two laser substrates 51a and 51b are not bonded in parallel with each other, for example, supply of both the laser beam from the first semiconductor laser element 52 to the second semiconductor laser element 53 and the laser beam from the second semiconductor laser element 53 to the first semiconductor laser element 52 can be accurately achieved by disposing the first and second emitters 62 and 63 on the first and second laser substrates 51a and 51b with high accuracy.

Moreover, the first laser substrate 51a and the second laser substrate 51b are only required to have the sizes sufficient for containing the first and second emitters 62 and 63. Thus, the cost of the first and second laser substrates 51a and 51b can be reduced by decreasing the sizes of the first and second laser substrates 51a and 51b to the smallest possible sizes.

### Fourth Embodiment

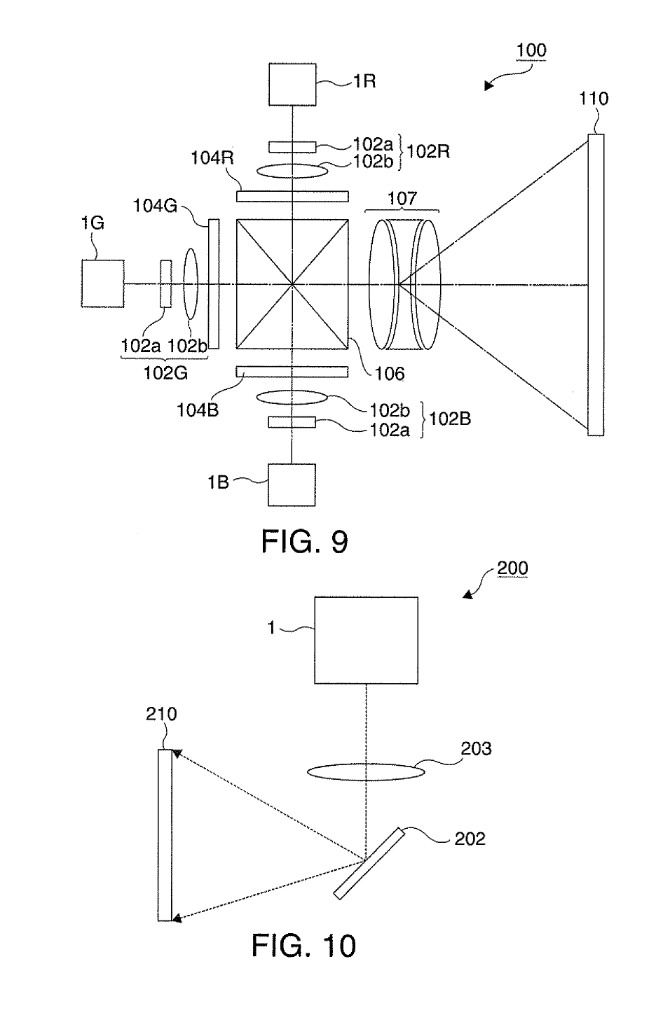

A fourth embodiment according to the invention is now described with reference to FIG. 9.

In this embodiment, a projector including the light source devices according to the first, second, or third embodiment will be discussed. FIG. 9 illustrates the general structure of the projector according to this embodiment.

A projector 100 in this embodiment includes a red laser beam source device 1R for emitting red light, a green laser beam source device 1G for emitting green light, and a blue laser beam source device 1B for emitting blue light, each of which corresponds to the light source device 1, 30, or 50 according to the first, second, or third embodiment.

The projector 100 includes transmission type liquid crystal light valves (light modulation devices) 104R, 104G, and 104B for modulating respective color lights emitted from the laser beam source devices 1R, 1G, and 1B, a cross dichroic prism (color combining unit) 106 for combining the lights received from the liquid crystal light valves 104R, 104G, and 104B and guiding the combined light to a projection lens 107, and the projection lens (projection unit) 107 for expanding an image formed by the liquid crystal light valves 104R, 104G, and 104E and projecting the expanded image on a screen 110.

The projector 100 further includes equalizing systems 1028, 102G, and 102B for equalizing illuminance distributions of the laser beams emitted from the laser beam source devices 1R, 1G, and 1B such that illumination lights having uniform illuminance distributions can be supplied to the liquid crystal light valves 104R, 104G, and 104B. In this embodiment, each of the equalizing systems 102R, 102G, and 102B contains a hologram 102a and a field lens 102b, for example.

The three color lights modulated by the respective liquid crystal light valves 104R, 104G, and 104B enter the cross dichroic prism 106. This prism is produced by affixing four rectangular prisms, and has a dielectric multilayer film for reflecting red light and a dielectric multilayer film for reflecting blue light disposed in a cross shape on the inner surfaces of the prisms. The three color lights are combined by these dielectric multilayer films to form light representing a color image. Then, the combined light is projected on the screen 110 by using the projection lens 107 as the projection system for display of the expanded image.

According to this embodiment, the projector 100 includes the red laser beam source device 1R, the green laser beam source device 1G, and the blue laser beam source device 1B each corresponding to the light source device 1, 30, or 50 according to the first, second, or third embodiment. Thus, the projector 100 becomes a compact and low-cost projector capable of displaying bright images.

While the transmission-type liquid crystal light valves are used as the light modulation devices, the light modulation devices may be reflection-type light valves or light valves of types other than the liquid crystal type. Examples of these light valves involve reflection-type liquid crystal light valves and digital micromirror devices. The structure of the projection system is changed according to the types of light valves to be used.

### Fifth Embodiment

A fifth embodiment according to the invention is now described with reference to FIG. 10.

In this embodiment, a scanning-type image display apparatus will be discussed. FIG. 10 illustrates the general structure of the image display apparatus according to this embodiment.

As illustrated in FIG. 10, an image display apparatus 200 in this embodiment includes the laser beam source device 1 according to the first embodiment, an MEMS mirror (scanning unit) 202 which applies light emitted from the laser beam source device 1 toward a screen 210 for scanning, and a converging lens 203 for converging the light emitted from the laser beam source device 1 on the MEMS mirror 202. The light received from the laser beam source device 1 is applied to the screen 210 in the horizontal direction and the vertical direction for scanning by driving the MEMS mirror 202. For display of color images, plural emitters contained in laser diodes are constituted by combinations of emitters having peak wavelengths in red, green, and blue, for example.

In this embodiment, the laser beam source devices 30 and 50 according to the second and third embodiments may be used.

### Sixth Embodiment

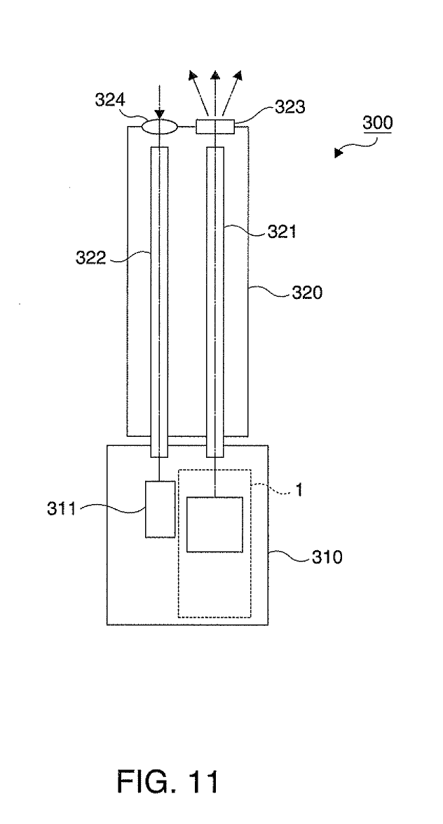

A structure example of a monitoring device 300 which uses the laser beam source device 1 according to the embodiment is now described with reference to FIG. 11.

FIG. 11 illustrates the general structure of the monitoring device according to this embodiment.

As illustrated in FIG. 11, the monitoring device 300 in this embodiment includes a device main body 310 and a light transmitting unit 320. The device main body 310 contains the laser beam source device 1 according to the first embodiment.

The light transmitting unit 320 includes two light guides 321 and 322 on the light sending side and the light receiving side, respectively. Each of the light guides 321 and 322 is produced by binding a number of optical fibers and can transmit laser beams to a distant place. The laser beam source device 1 is provided on the light entrance side of the light guide 321 for sending light, and a diffusion plate 323 is disposed on the light exit side of the light guide 321. The laser beam emitted from the laser beam source device 1 is transmitted to the diffusion plate 323 provided at the end of the light transmitting unit 320 via the light guide 321, diffused by the diffusion plate 323, and applied to a subject.

An image forming lens 324 is equipped at the end of the light transmitting unit 320 such that reflection light from the subject can be received by the image forming lens 324. The received reflection light is transmitted via the light guide 322 on the light receiving side to a camera 311 as an image pickup unit provided within the device main body 310. As a result, an image corresponding to the light reflected by the subject can be captured by the camera 311 by using the laser beam emitted from the laser beam source device 1 and applied to the subject.

According to this embodiment, the monitoring device 300 includes the laser beam source device 1 in the first embodiment. Thus, the monitoring device 300 becomes a compact and low-cost device capable of capturing clear images.

In this embodiment, the laser beam source devices 30 and 50 according to the second and third embodiments may be used.

The technical range of the invention is not limited to the embodiments described herein but may be modified in various ways without departing from the scope and spirit of the invention. For example, the specific structures of the laser diodes, the wavelength selecting mirrors, the wavelength converting elements included in the laser beam source devices in the first and second embodiments are not limited to those shown herein but may be varied as necessary.

A technical concept possible in light of the teachings of the embodiments and modified examples described herein but not included in the appended claims is now explained along with the advantages provided by the concept.

A laser beam source device includes: a first light emission element having an emission portion for emitting a laser beam; a second light emission element having a light emission portion for emitting a laser beam; and first and second dividing units disposed on optical paths of the laser beams emitted from the first light emission element and the second light emission element to release a part of the received laser beams in directions different from directions toward the first light emission element and the second light emission element and release the remaining part of the laser beams in directions toward the first light emission element and the second light emission element. In this case, the first light emission element and the second light emission element are provided on a laser substrate in correspondence with each other such that the laser beams emitted from the light emission portion of each of the light emission elements can enter the light emission portion of the other light emission element.

According to this structure, the laser beam emitted from the light emission portion of the first light emission element enters the light emission portion of the second light emission element, and the laser beam emitted from the light emission portion of the second light emission element enters the light emission portion of the first light emission element. A part of the laser beams having reciprocated between the light emission portion of the first light emission element and the light emission portion of the second light emission element are released in directions different from directions toward the first and second light emission element by the function of the first and second dividing units. The remaining part of the laser beams are released toward the first and second light emission elements by the function of the first and second dividing units.

In this structure, the first light emission element and the second light emission element are disposed on the one laser substrate in correspondence with one another such that the laser beam emitted from the light emission portion of each of the light emission elements can enter the light emission portion of the other light emission element. In this case, the laser beams can be supplied to the opposed light emission element with high accuracy. Thus, the laser beams emitted from the respective light emission portions of the first and second light emission elements can enter the opposed light emission elements without loss of laser beams. Accordingly, the efficiency of using light improves, and the output increases.

A laser beam source device has the following points: each of the first light emission element and the second light emission element has the plural light emission portions; the arrangement direction of the plural light emission portions of the first light emission element is substantially parallel with the arrangement direction of the plural light emission portions of the second light emission element; the clearance between each pair of the adjoining light emission portions of the first light emission element is substantially equal to the clearance between each pair of the adjoining light emission portions of the second light emission element; the laser beams emitted from the plural light emission, portions of the first light emission element enter the first dividing unit; and the laser beams emitted from the plural light emission portions of the second light emission element enter the second dividing unit.

According to this structure, the arrangement direction of the plural light emission portions of the first light emission element is substantially parallel with the arrangement direction of the plural light emission portions of the second light emission element, and the clearance between each pair of the adjoining light emission portions of the first light emission element is substantially equal to the clearance between each pair of the adjoining light emission portions of the second light emission element. In this arrangement, the plural light emission portions of the first light emission element and the plural light emission portions of the second light emission element are accurately aligned. Thus, the laser beams emitted from the plural light emission portions of the one light emission element can be accurately supplied toward the other laser beams.

Moreover, the laser beams emitted from the plural light emission portions of the first light emission element enter the first dividing unit, and the laser beams emitted from the plural light emission portions of the second light emission element enter the second dividing unit. In this case, the plural laser beams can be collectively divided, and thus the first and second dividing units can be easily positioned.

A laser beam source device has the following points: each of the plural light emission portions of the first and second light emission elements has a red light emission portion for emitting red light, a green light emission portion for emitting green light, and a blue light emission portion for emitting blue light; and the red light emission portions, the green light emission portions, and the blue light emission portions of the first and second light emission elements as pairs of light emission portions for emitting the same color lights are disposed in this order from the ends of the laser substrate toward the center.

According to this structure, the red light emission portions, the green light emission portions, and the blue light emission portions are provided on the same laser substrate. Thus, the number of the light emission portions formed on the one laser substrate increases.

Moreover, the pairs of the light emission portions for emitting the same color lights are disposed from the ends of the laser substrate toward the center. Thus, the optical path lengths of the laser beams emitted from the respective light emission portions can be made substantially equivalent by controlling the positions of the first and second dividing units.

A laser beam source device manufacturing method includes: disposing a first laser substrate and a second laser substrate on a supporting substrate and bonding the first laser substrate and the second laser substrate to the supporting substrate; forming first and second light emission portions for emitting laser beams on the first and second laser substrates, respectively, after the bonding step is finished; and disposing first and second dividing units on the optical paths of the laser beams emitted from the first and second light emission elements, respectively, as units for dividing the received laser beams according to the conditions of the laser beams.

According to this manufacturing method, the first laser substrate and the second laser substrate are disposed on the supporting substrate, and the first laser substrate and the second laser substrate are bonded to the supporting substrate. Then, the first light emission portion for emitting a laser beam is formed on the first laser substrate, and the second light emission portion for emitting a laser beam is formed on the second laser substrate. In this case, the first and second light emission portions can be accurately formed on the first and second laser substrates even when the first and second laser substrates are not bonded in parallel with each other at the time of bonding the two laser substrates to the supporting substrate, for example. Thus, the laser beam emitted from the light emission portion of each of the light emission elements can accurately enter the light emission portion of the other light emission element.

Moreover, the first laser substrate and the second laser substrate are only required to have the sizes sufficient for containing the first and second light emission portions. Thus, the cost of the laser substrates can be reduced by decreasing the sizes of the first and second laser substrates to the smallest possible sizes.

The entire disclosure of Japanese Patent Application No. 2009-269675, filed Nov. 27, 2009 is expressly incorporated by reference herein.

What is claimed is:

1. A laser beam source device comprising:
a first light emission element having first and second light emission portions each of which emits a laser beam;
a second light emission element having first and second light emission portions each of which emits a laser beam; and
first and second dividing units disposed on optical paths of the laser beams emitted from the first light emission element and the second light emission element, respectively, to release a part of the received laser beams in directions different from directions toward the first light emission element and the second light emission element and release the remaining part of the laser beams in directions toward the first light emission element and the second light emission element,
wherein
the first light emission portion of the first light emission element and the first light emission portion of the second light emission element are disposed in correspondence with each other such that the laser beam emitted from each of the light emission portions can enter the other light emission portion,
the second light emission portion of the first light emission element and the second light emission portion of the second light emission element are disposed in correspondence with each other such that the laser beam emitted from each of the light emission portions enters the other light emission portion, and
the clearance between the first light emission portion of the first light emission element and the first light emission portion of the second light emission element is longer than the clearance between the second light emission portion of the first light emission element and the second light emission portion of the second light emission element.

2. The laser beam source device according to claim 1, wherein the first dividing unit and the second dividing unit are disposed on the optical paths such that the optical path length between the first light emission portion of the first light emission element and the first dividing unit is shorter than the optical path length between the second light emission portion of the first light emission element and the first dividing unit, that the optical path length between the first light emission portion of the second light emission element and the second dividing unit is shorter than the optical path length between the second light emission portion of the second light emission element and the second dividing unit, and that the optical path lengths of the laser beams emitted from the first light emission portions between the first dividing unit and the second dividing unit are longer than the optical path lengths of the laser beams emitted from the second light emission portions between the first dividing unit and the second dividing unit.

3. The laser beam source device according to claim 1, wherein
each of the first light emission portion of the first light emission element and the first light emission portion of the second light emission element has a plurality of light emission sections:
the arrangement direction of the plural light emission sections of the first light emission portion of the first light emission element extends substantially in parallel with the arrangement direction of the plural light emission sections of the first light emission portion of the second light emission element;
the clearance between each pair of the adjoining light emission sections of the first light emission portion of the first light emission element is substantially equal to the clearance between each pair of the adjoining light emission sections of the first light emission portion of the second light emission element;
laser beams emitted from the plural light emission sections of the first light emission element enter the first dividing unit; and
laser beams emitted from the plural light emission sections of the second light emission element enter the second dividing unit.

4. The laser beam source device according to claim 1, wherein the color of the light emitted from the first light emission portion is different from the color of the light emitted from the second light emission portion.

5. The laser beam source device according to claim 4, wherein
each of the first light emission element and the second light emission element has the first light emission portion, the second light emission portion, and a third light emission portion;
the color of the light emitted from the third light emission portion is different from the colors of the lights emitted from the first light emission portion and the second light emission portion;
the clearance between the respective first light emission portions of the first light emission element and the second light emission element is longer than the clearance between the respective second light emission portions of the first light emission element and the second light emission element; and
the clearance between the respective second light emission portions of the first light emission element and the second light emission element is longer than the clearance between the respective third light emission portions of the first light emission element and the second light emission element.

6. The laser beam source device according to claim 1, further comprising:
a wavelength converting element disposed on the optical path between the first dividing unit and the second dividing unit to receive respective laser beams having a fundamental wavelength and emitted from the first light emission element and the second light emission element and convert at least a part of the laser beams having the fundamental wavelength into laser beams having a predetermined converted wavelength,
wherein the first and second dividing units release the converted laser beams having the predetermined converted wavelength in directions different from directions toward the first and second light emission elements and release the laser beams having the fundamental wavelength and not converted into beams of the predetermined converted wavelength in directions toward the first and second light emission elements.

7. The laser beam source device according to claim 1, wherein the light emission portion of the first light emission element and the light emission portion of the second light emission element are provided on a laser substrate.

8. A laser beam source device manufacturing method for manufacturing the laser beam source device according to claim 1, comprising
forming the first light emission element and the second light emission element on the laser substrate by using photolithography.

9. A projector comprising:
the laser beam source device according to claim 1;
a light modulation device which modulates a laser beam emitted from the laser beam source device according to an image signal; and
a projection device which projects light modulated by the light modulation device.

10. A monitoring device comprising:
the laser beam source device according to claim 1; and
an image pickup unit which captures an image of a subject by using light emitted from the laser beam source device.
